(19) United States
(12) Patent Application Publication
(10) Pub. No.: US 2010/0295160 A1
(43) Pub. Date: Nov. 25, 2010

(54) QUAD FLAT PACKAGE STRUCTURE HAVING EXPOSED HEAT SINK, ELECTRONIC ASSEMBLY AND MANUFACTURING METHODS THEREOF

(75) Inventors: CHUN-CHEN LIU, Kaohsiung County (TW); Yu-Ren Chu, Kaohsiung County (TW)

Correspondence Address: J C PATENTS, 4 VENTURE, SUITE 250, IRVINE, CA, 92618, US

(73) Assignee: Advanced Semiconductor Engineering, Inc., Kaohsiung (TW)

(21) Appl. No.: 12/703,498

(22) Filed: Feb. 10, 2010

Related U.S. Application Data
(60) Provisional application No. 61/180,434, filed on May 22, 2009.

(30) Foreign Application Priority Data
Jun. 30, 2009 (TW) 98122148

(51) Int. Cl. H01L 23/34; H01L 21/60

(52) U.S. Cl. 257/675; 438/122; 257/E23.08; 257/E23.031; 257/E21.506

(57) ABSTRACT

A quad flat package (QDP) structure having an exposed heat sink is provided. The QDP structure includes a leadframe, a chip, a heat sink, an insulating layer and a molding compound. The leadframe includes a die pad and multiple leads surrounding the die pad. The chip is disposed on the die pad and electrically connected to the die pad and the leads. The heat sink has a top surface, a bottom surface opposite thereto, and a side surface connected to the top and the bottom surfaces. The die pad is disposed in a central area of the top surface of the heat sink and electrically connected to the heat sink. The molding compound encapsulates the chip, the die pad, an inner lead portion of each lead and heat sink, and exposes the bottom surface of the heat sink and an outer lead portion of each lead.

### CROSS-REFERENCE TO RELATED APPLICATION

This application claims the priority benefit of U.S. provisional application Ser. No. 61/180,434, filed on May 22, 2009 and Taiwan application serial no. 98122148, filed Jun. 30, 2009. The entirety of each of the above-mentioned patent applications is hereby incorporated by reference herein and made a part of specification.

### BACKGROUND OF THE INVENTION

1. Field of the Invention

The present invention relates to a semiconductor manufacturing method and a structure thereof. More particularly, the present invention relates to a package method and a structure thereof.

2. Description of Related Art

To reduce a size of an integrated circuit product is always a long-term target in electronics manufacturing industry. Reduction of the product size can reduce a fabrication cost and shorten a signal transmission path, and meanwhile improve a product performance.

One of the main factors that influence the size of the integrated circuit device is improvement of a package technique. Presently, a package method of using a leadframe as a chip carrier is still a popularised and widely used technique, in which a quad flat package (QFP) structure is a commonly used one.

The QFP structure mainly includes a leadframe, a chip, a heat sink and a molding compound. The leadframe includes a die pad and a plurality of leads surrounding the die pad. The chip is disposed on an upper surface of the die pad and is electrically connected to the leads of the leadframe through a wire bonding technique. The die pad is disposed on the heat sink through its lower surface, so that heat generated during operation of the chip can be dissipated to external through the die pad and the head sink. The molding compound encapsulates the leadframe, the chip, and the heat sink to protect these devices from damage and humidity.

### SUMMARY OF THE INVENTION

The present invention is directed to a quad flat package (QFP) structure having an exposed heat sink, in which a chip is electrically connected to an external circuit through a die pad and the heat sink located under the die pad.

The present invention is directed to a QFP structure having an exposed heat sink, in which an insulating layer covers a side surface and a peripheral area of a top surface of the heat sink, so that during a molding process, a situation that an inner lead portion of each lead located above the peripheral area of the top surface of the heat sink contacts the heat sink to form a short-circuit due to a hydraulic pressure generated by plastic potting can be avoided, so as to maintain a good production yield.

The present invention is directed to an electronic assembly, which has a better electrical performance and heat-dissipation capacity.

The present invention is further directed to a manufacturing method of the aforementioned QFP structure, and a manufacturing method of the electronic assembly.

The present invention provides a QFP structure having an exposed heat sink includes a leadframe, a chip, a heat sink, and a molding compound. The leadframe includes a die pad and a plurality of leads surrounding the die pad, wherein the die pad has an upper surface and a lower surface opposite to the upper surface, and each lead has an inner lead portion and an outer lead portion. The chip is disposed on the upper surface of the die pad and is electrically connected to the die pad and the leads of the leadframe. The heat sink has a top surface, a bottom surface opposite to the top surface, and a side surface connected between the top and the bottom surfaces, wherein the top surface has a central area and a peripheral area surrounding the central area. The die pad is disposed in the central area of the top surface of the heat sink through its lower surface, and is electrically connected to the heat sink. The inner lead portion of each lead is disposed above the peripheral area. The molding compound encapsulates the chip, the die pad, the inner lead portion of each lead and the heat sink, and exposes the bottom surface of the heat sink and the outer lead portion of each lead, wherein the bottom surface of the heat sink can be electrically conducted to external.

In an embodiment of the present invention, the QFP structure having the exposed heat sink further includes an insulating layer, wherein the insulating layer at least covers the peripheral area of the top surface or the side surface of the heat sink.

In an embodiment of the present invention, the heat sink has a containing groove disposed in the central area, and the die pad is disposed in the containing groove.

In an embodiment of the present invention, the QFP structure having the exposed heat sink further includes at least a first bonding wire and at least a second bonding wire, wherein the first bonding wire is electrically connected to the inner lead portion of the corresponding lead and the chip, and the second bonding wire is electrically connected to the chip and the die pad.

In an embodiment of the present invention, the QFP structure having the exposed heat sink further includes at least a third bonding wire, wherein the third bonding wire is electrically connected to the die pad and the inner lead portion of the corresponding lead.

In an embodiment of the present invention, a material of the first bonding wire and the second bonding wire includes gold, copper, silver, aluminium or alloys thereof.

In an embodiment of the present invention, a material of the third bonding wire includes gold, copper, silver, aluminium or alloys thereof.

In an embodiment of the present invention, the QFP structure having the exposed heat sink further includes a first adhesion layer disposed between the chip and the die pad.

In an embodiment of the present invention, a material of the first adhesion layer is a conductive adhesive.

In an embodiment of the present invention, the QFP structure having the exposed heat sink further includes a second adhesion layer disposed between the die pad and the heat sink.

In an embodiment of the present invention, a material of the second adhesion layer is a conductive adhesive.

In an embodiment of the present invention, a material of the second adhesion layer is a conductive adhesive plus a copper sheet.

In an embodiment of the present invention, the bottom surface of the head sink and the lower surface of the molding compound are coplanar.

In an embodiment of the present invention, a material of the heat sink includes copper or aluminium.

In an embodiment of the present invention, the QFP structure having the exposed heat sink further includes a wetting layer, wherein the wetting layer is disposed on the bottom surface of the heat sink, and covers the bottom surface of the heat sink.

In an embodiment of the present invention, a material of the wetting layer includes tin or tin alloy.

The present invention provides an electronic assembly including a QFP structure, a circuit board, at least one solder mask layer and a solder layer. The QFP structure includes a leadframe, a chip, a heat sink, and a molding compound. The leadframe includes a die pad and a plurality of leads surrounding the die pad, wherein the die pad has an upper surface and a lower surface opposite to the upper surface, and each lead has an inner lead portion and an outer lead portion. The chip is disposed on the upper surface of the die pad and is electrically connected to the die pad and the leads of the leadframe. The heat sink has a top surface, a bottom surface opposite to the top surface, and a side surface connected between the top and the bottom surfaces, wherein the top surface has a central area and a peripheral area surrounding the central area. The die pad is disposed in the central area of the top surface of the heat sink through its lower surface, and is electrically connected to the heat sink. The inner lead portion of each lead is disposed above the peripheral area. The molding compound encapsulates the chip, the die pad, the inner lead portion of each lead and the heat sink, and exposes the bottom surface of the heat sink and the outer lead portion of each lead, wherein the bottom surface of the heat sink can be electrically conducted to external. The QFP structure is disposed on the circuit board, and the circuit board has a first surface and a second surface opposite to the first surface, wherein the first surface is covered with at least a patterned conductive layer and at least a wiring layer. The patterned conductive layer has at least a first pad and at least a second pad, wherein the first pad is electrically connected to the bottom surface of the heat sink, and the second pad is electrically connected to at least one end of the outer lead portion. The solder mask layer is disposed on the patterned conductive layer, and at least one opening of the solder mask layer exposes the first pad and the second pad. The solder layer is disposed between the bottom surface of the heat sink of the QFP structure and the circuit board, and between the outer lead portions and the circuit board, and is electrically connected to the QFP structure and the circuit board.

In an embodiment of the present invention, the QFP structure further includes an insulating layer, wherein the insulating layer at least covers the side surface or the peripheral area of the top surface of the heat sink.

In an embodiment of the present invention, the first pad is a power pad or a ground pad.

In an embodiment of the present invention, the second pad is a signal pad or a ground pad.

In an embodiment of the present invention, a material of the solder layer includes tin or tin alloy.

In an embodiment of the present invention, the QFP structure further includes at least a first bonding wire and at least a second bonding wire, wherein the first bonding wire is electrically connected between the inner lead portion of the corresponding lead and the chip, and the second bonding wire is electrically connected between the chip and the die pad.

In an embodiment of the present invention, the QFP structure further includes at least a third bonding wire, wherein the third bonding wire is electrically connected between the die pad and the inner lead portion of the corresponding lead.

In an embodiment of the present invention, a material of the first bonding wire and the second bonding wire includes gold, copper, silver, or alloys thereof.

In an embodiment of the present invention, a material of the third bonding wire includes gold, copper, silver, or alloys thereof

In an embodiment of the present invention, the QFP structure further includes a first adhesion layer disposed between the chip and the die pad.

In an embodiment of the present invention, a material of the first adhesion layer is a conductive adhesive.

In an embodiment of the present invention, the QFP structure further includes a second adhesion layer disposed between the die pad and the heat sink.

In an embodiment of the present invention, a material of the second adhesion layer is a conductive adhesive.

In an embodiment of the present invention, a material of the second adhesion layer is a conductive adhesive plus a copper sheet.

In an embodiment of the present invention, the bottom surface of the head sink and the lower surface of the molding compound are coplanar.

In an embodiment of the present invention, a material of the heat sink includes copper or aluminium.

In an embodiment of the present invention, the QFP structure further includes a wetting layer, wherein the wetting layer is disposed between the bottom surface of the heat sink and the solder layer, and covers the bottom surface of the heat sink.

In an embodiment of the present invention, a material of the wetting layer includes tin or tin alloy.

The present invention provides a manufacturing method of a QFP structure having an exposed heat sink. First, the heat sink is provided, wherein the heat sink has a top surface, a bottom surface opposite to the top surface, and a side surface connected between the top and the bottom surfaces, wherein the top surface has a central area and a peripheral area surrounding the central area. Next, a leadframe is bonded to the heat sink, wherein the leadfram includes a die pad and a plurality of leads surrounding the die pad, wherein the die pad has an upper surface and a lower surface opposite to the upper surface, the die pad is disposed in the central area of the top surface of the heat sink through its lower surface, and is electrically connected to the heat sink Each lead has an inner lead portion and an outer lead portion, and the inner lead portion of each lead is disposed above the peripheral area. Next, a chip is bonded to the upper surface of the die pad, wherein the chip is electrically connected to the die pad and the leads of the leadframe. Next, a molding compound is formed to encapsulate the chip, the die pad, the inner lead portion of each lead and the heat sink, and expose the bottom surface of the heat sink and the outer lead portion of each lead, wherein the bottom surface of the heat sink can be electrically conducted to external.

In an embodiment of the present invention, the manufacturing method of the QFP structure having the exposed heat sink further includes forming an insulating layer on the heat sink, wherein the insulating layer at least covers the peripheral area of the top surface or the side surface of the heat sink.

In an embodiment of the present invention, at least one inner lead portion is electrically connected to the chip through a first wire bonding approach, and the die pad is electrically connected to the chip through a second wire bonding approach.

In an embodiment of the present invention, at least one inner lead portion is electrically connected to the die pad through a third wire bonding approach.

In an embodiment of the present invention, a material of the first bonding wire and the second bonding wire includes gold, copper, silver, aluminium or alloys thereof.

In an embodiment of the present invention, a material of the third bonding wire includes gold, copper, silver, aluminium or alloys thereof.

In an embodiment of the present invention, the manufacturing method of the QFP structure having the exposed heat sink further includes forming a first adhesion layer between the chip and the die pad.

In an embodiment of the present invention, a material of the first adhesion layer is a conductive adhesive.

In an embodiment of the present invention, the manufacturing method of the QFP structure having the exposed heat sink further includes forming a second adhesion layer between the die pad and the heat sink.

In an embodiment of the present invention, a material of the second adhesion layer is a conductive adhesive.

In an embodiment of the present invention, a material of the second adhesion layer is a conductive adhesive plus a copper sheet.

In an embodiment of the present invention, the bottom surface of the head sink and the lower surface of the molding compound are coplanar.

In an embodiment of the present invention, a material of the heat sink includes copper or aluminium.

In an embodiment of the present invention, the step of forming the insulating layer on the heat sink includes following steps. First, an adhesive tape is adhered to the bottom surface or the central area of the top surface of the heat sink. Next, the insulating layer is formed on the side surface or the peripheral area of the top surface of the heat sink by electroplating. Finally, the adhesive tape is removed to expose the bottom surface and the central area of the top surface of the heat sink.

In an embodiment of the present embodiment, before the adhesive tape is adhered to the heat sink, a containing groove is formed in the central area of the heat sink, and the die pad is located in the containing groove.

In an embodiment of the present embodiment, the manufacturing method of the QFP structure having the exposed heat sink further includes forming a wetting layer on the bottom surface of the heat sink by electroplating to cover the bottom surface of the heat sink.

In an embodiment of the present embodiment, a material of the wetting layer includes tin or tin alloy.

The present invention provides a manufacturing method of an electronic assembly. First, a QFP structure is provided, the QFP structure has a leadframe, a chip, a heat sink, and a molding compound, wherein the leadframe includes a die pad and a plurality of leads surrounding the die pad, each lead has an inner lead portion and an outer lead portion, the heat sink has a top surface, a bottom surface opposite to the top surface, wherein the top surface has a central area, the molding compound encapsulates the chip, the die pad, the inner lead portion of each lead and the heat sink, and exposes the bottom surface of the heat sink and the outer lead portion of each lead, and the die pad is disposed in the central area of the top surface of the heat sink, so that the chip is electrically connected to the heat sink through the die pad. Next, a circuit board is provided, the circuit board has a first surface and a second surface opposite to the first surface, wherein the first surface is covered with at least a patterned conductive layer and at least a wiring layer, the patterned conductive layer has at least a first pad and at least a second pad, wherein the first pad is electrically connected to the bottom surface of the heat sink, and the second pad is electrically connected to at least one end of the outer lead portion. Next, a solder mask layer is formed on the patterned conductive layer, wherein at least one opening of the solder mask layer exposes the first pad and the second pad. Next, a solder layer is fowled between the bottom surface of the heat sink and the circuit board, and between the outer lead portion and the circuit board, and the QFP structure is electrically connected to the circuit board.

In an embodiment of the present invention, the QFP structure further includes an insulating layer formed on the heat sink, wherein the insulating layer at least covers the peripheral area of the top surface or the side surface of the heat sink.

In an embodiment of the present invention, the bottom surface of the head sink and the lower surface of the molding compound are coplanar.

In an embodiment of the present invention, the QFP structure further includes a wetting layer disposed between the bottom surface of the heat sink and the solder layer.

According to the above descriptions, since the insulating layer of the package structure of the present invention covers the side surface or the peripheral area of the top surface of the heat sink, during the molding process, a situation that the inner lead portion of each lead located above the peripheral area of the top surface of the heat sink contacts the heat sink to form a short-circuit due to a hydraulic pressure generated by plastic potting can be avoided, so as to maintain a good production yield. Moreover, since the insulating layer does not cover the bottom surface and the central area of the top surface of the heat sink, when the die pad of the leadframe is disposed in the central area of the top surface of the heat sink, and the chip is disposed on the die pad, the die pad can be electrically connected to the heat sink directly, and the chip can be electrically connected to external circuit through the die pad and the heat sink under the die pad, so that the heat generated by the chip can be quickly dissipated to external through an area of the heat sink that is uncovered by the insulating layer. Therefore, the package structure of the present invention has a better electrical performance and heat-dissipation capacity.

In order to make the aforementioned and other features and advantages of the present invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a package structure according to an embodiment of the present invention.

FIG. 2 is a flowchart illustrating a manufacturing method of a package structure according to an embodiment of the present invention.

FIGS. 3A-3C are cross-sectional views illustrating a process of forming an insulating layer on a heat sink according to an embodiment of the present invention.

FIG. 4 is a cross-sectional view of a package structure according to another embodiment of the present invention.

FIG. 5 is a cross-sectional view of a package structure according to another embodiment of the present invention.

FIG. 6 is a top view of a circuit board of FIG. 5.

### DESCRIPTION OF THE EMBODIMENTS

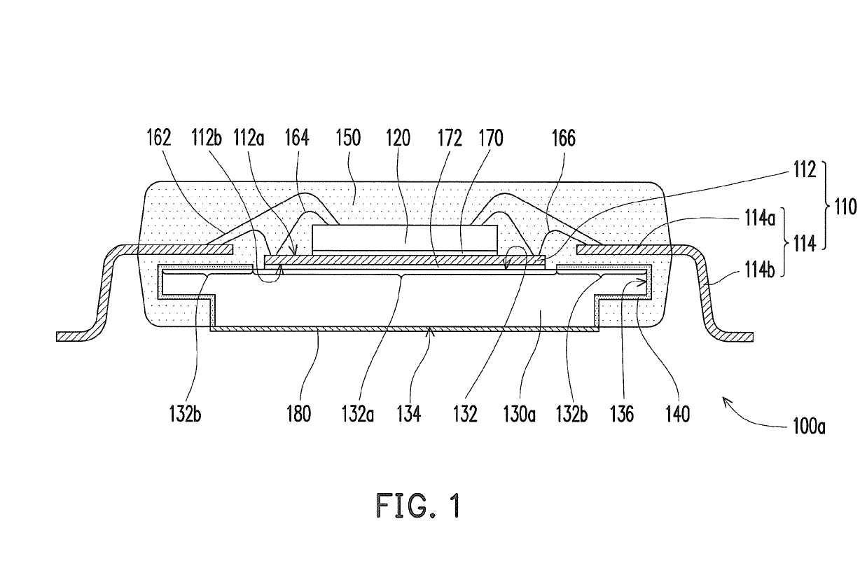

FIG. 1 is a cross-sectional view of a package structure according to an embodiment of the present invention. Referring to FIG. 1, in the present embodiment, the package structure 100a includes a leadframe 110, a chip 120, a heat sink 130a and a molding compound 150.

The leadframe 110 includes a die pad 112 and a plurality of leads 114 surrounding the die pad 112, wherein the die pad 112 is used for carrying the chip 120, and the leads 114 are used for electrically connecting the chip 120. In detail, the die pad 112 has an upper surface 112a and a lower surface 112b opposite to the upper surface 112a, and each lead 114 has an inner lead portion 114a and an outer lead portion 114b. The chip 120 is disposed on the upper surface 112a of the die pad 112 and is electrically connected to the die pad 112 and the leads 114 of the leadframe 110.

In the present embodiment, the chip 120 is fixed on the upper surface 112a of the die pad 112 through a first adhesion layer 170, and the chip 120 is electrically connected to the die pad 112 and the leads 114 of the leadframe 110 through a plurality of first bonding wires 162 and a plurality of second bonding wires 164 formed according to a wire bonding technique. Namely, the first bonding wire 162 is connected between the inner lead portion 114a of the corresponding lead 114 and the chip 120, and the second bonding wire 164 is connected between the chip 120 and the die pad 112. A material of the first bonding wire 162 and the second bonding wire 164 can be gold, copper, silver, aluminium or alloys thereof Moreover, the die pad 112 is electrically connected to the inner lead portions 114a of the leads 114 through a plurality of third bonding wires 166 formed according to the wire bonding technique, i.e. the third bonding wire 166 is connected to the die pad 112 and the inner lead portions 114a of the corresponding lead 114. A material of the third bonding wire 166 can be gold, copper, silver, aluminium or alloys thereof. Moreover, a material of the first adhesion layer 170 is a conductive adhesive, for example, silver paste.

It should be noticed that in the present embodiment, a same wire bonding process can be performed to electrically connect the inner lead portion 114a of each lead 114 and the die pad 112 to the chip 120, and electrically connect the inner lead portion 114a of each lead 114 to the die pad 112. Namely, the first bonding wires 162 electrically connected to the leads 114 and the chip 120, the second bonding wire 164 electrically connected to the chip 120 and the die pad 112, and the third bonding wires 166 electrically connected to the die pad 112 and the leads 114 are simultaneously formed. However, the chip 120 can also be connected to the leads 114 and the die pad 112 of the leadframe 110 through other approaches, for example, a flip-chip bonding technique. Therefore, an electrical connecting approach between the chip 120 and the leadframe 110 is not limited by the present invention.

The heat sink 130a has a top surface 132, a bottom surface 134 opposite to the top surface 132, and a side surface 136 connected between the top surface 132 and the bottom surface 134, wherein the top surface 132 has a central area 132a and a peripheral area 132b surrounding the central area 132a. The die pad 112 is disposed in the central area 132a of the top surface 132 of the heat sink 130a through its lower surface 112a, and is electrically connected to the heat sink 130a, so that the heat generated by the chip 120 can be dissipated to external through the die pad 112 and the heat sink 130a. The inner lead portion 114a of each lead 114 is disposed above the peripheral area 132b of the top surface 132 of the heat sink 130a. Moreover, a material of the heat sink 130a can be metal, for example, copper or aluminium, or other materials with good thermal conductivity.

In the present embodiment, the package structure 100a further includes a second adhesion layer 172, wherein the second adhesion layer 172 is disposed between the die pad 112 and the heat sink 130a, and is used for increasing adhesion and conductivity between the die pad 112 and the heat sink 130a. A material of the second adhesion layer 172 is, for example, a conductive adhesive or a conductive adhesive plus a copper sheet. Moreover, the package structure 100a can further include an insulating layer 140, wherein the insulating layer 140 at least covers the side surface 136 or the peripheral area 132b of the top surface 132 of the heat sink 130a. In other words, the insulating layer 140 does not cover the central area 132a of the top surface 132 of the heat sink 130a and the bottom surface 134 of the heat sink 130a.

The molding compound 150 encapsulates the chip 120, the die pad 112, the inner lead portion 114a of each lead 114 and the heat sink 130a, and exposes the bottom surface 134 of the heat sink 130a and the outer lead portion 114b of each lead 114, wherein the exposed bottom surface 134 of the heat sink 130a can be electrically conducted to external, and the bottom surface 134 of the heat sink 130a and the lower surface of the molding compound 150 are coplanar. Since the insulating layer 140 covers the peripheral area 132b of the top surface 132 of the heat sink 130a, namely, the peripheral area 132b of the top surface 132 of the heat sink 130a is an insulating area, during a molding process, a situation that the inner lead portion 114a of each lead 114 located above the peripheral area 132b of the top surface 132 of the heat sink 130a contacts the heat sink 130a to form a short-circuit due to a hydraulic pressure generated by plastic potting can be avoided. The outer lead portion 114b of each lead 114 can be bended downwards to form a suitable shape for connecting the external circuit.

Moreover, a wetting layer 180 can be coated on the exposed bottom surface 134 of the heat sink 130a by electroplating, i.e. the wetting layer 180 covers the bottom surface 134 of the heat sink 130a, by which besides a heat-dissipation capacity of the heat sink 130a is increased, when the package structure 100a is electrically connected to the external circuit, the wetting layer 180 can also function as an adhesion layer to increase the adhesion between the package structure 100a and the external circuit. In the present embodiment, a material of the wetting layer 180 is, for example, tin or tin alloy.

In detail, since the insulating layer 140 does not cover the bottom surface 134 and the central area 132a of the top surface 132 of the heat sink 130a, the bottom surface 134 and the central area 132a of the top surface 132 of the heat sink 130a has a better conductivity and heat-dissipation capacity. Therefore, the die pad 112 is electrically connected to the central area 132a of the top surface 132 of the heat sink 130a directly, and the chip 120 can be electrically connected to the external circuit through the die pad 112 and the heat sink 130a under the die pad 112, so that the heat generated by the chip 120 can be quickly dissipated to external through the heat sink 130a. Based on the heat sink 130a, the package structure 100a of the present embodiment not only has a better heat-dissipation capacity to maintain a normal operation of the chip 120, but also has a good electrical performance.

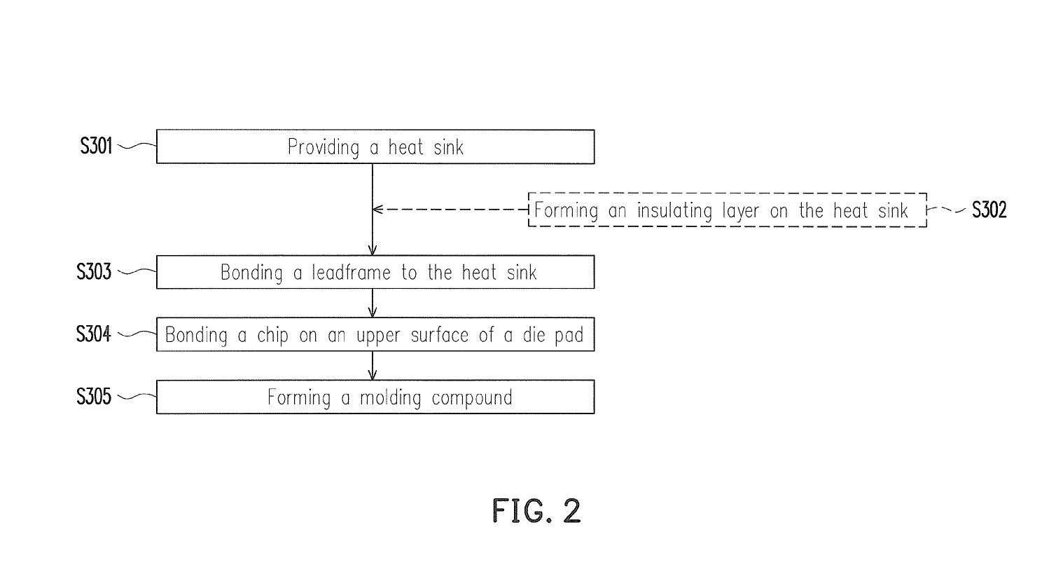

FIG. 2 is a flowchart illustrating a manufacturing method of the package structure 100a. Referring to FIG. 1 and FIG. 2, first, in step S301, the heat sink 130a is provided. As described above, the heat sink 130a has the top surface 132, the bottom surface 134 opposite to the top surface 132, and the side surface connected between the top surface 132 and the bottom surface 134, wherein the top surface 134 has a central area 132a and a peripheral area 132b surrounding the central area 132a, and a material of the heat sink 130a includes copper or aluminium.

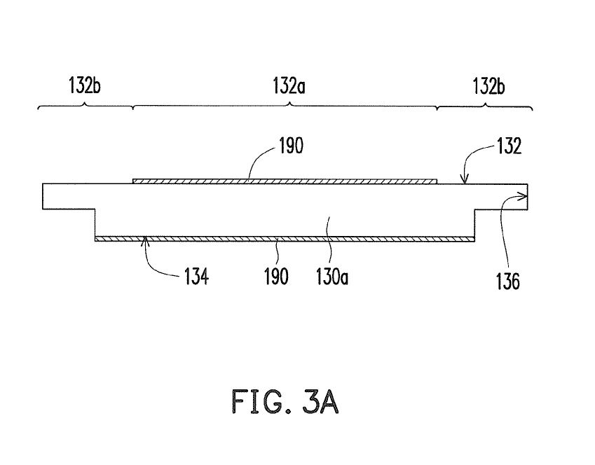

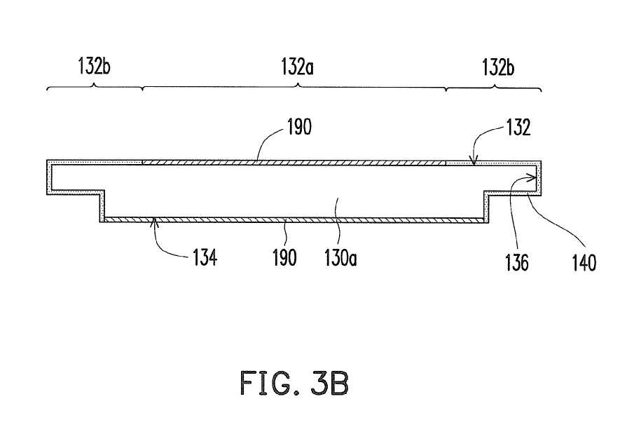

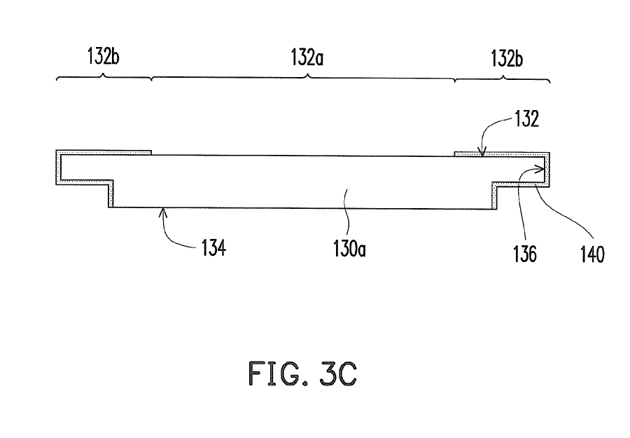

Next, in step 5302, the insulating layer 140 is formed on the heat sink 130a, wherein the insulating layer 140 at least covers the side surface 136 and the peripheral area 132b of the top surface 132 of the heat sink 130a. In detail, steps of forming the insulating layer 140 on the heat sink 130a can be described as follows. First, as shown in FIG. 3A, an adhesive tape 190 is adhered to the bottom surface 134 and the central area 132a of the top surface 132 of the heat sink 130a. Next, as shown in FIG. 3B, the insulating layer 140 is formed on the side surface 136 and the peripheral area 132b of the top surface 132 of the heat sink 130a by electroplating, i.e. the insulating layer 140 encapsulates the side surface 136 and the peripheral area 132b of the top surface 132 of the heat sink 130a. Finally, as shown in FIG. 3C, the adhesive tape 190 is removed to expose the bottom surface 134 and the central area 132a of the heat sink 130a.

To improve a heat-dissipation effect of the heat sink 130a, the wetting layer 180 can be formed on the bottom surface 134 of the heat sink 130a that is exposed by the insulating layer 140 via electroplating. The wetting layer 180 covers the bottom surface 134 of the heat sink 130a, and a material of the wetting layer 180 is, for example, tin or tin alloy. It should be noticed that besides the wetting layer 180 can be used to increase a heat-dissipation capacity of the heat sink 130a, when the package structure 100a is electrically connected to the external circuit, the wetting layer 180 can also function as an adhesion layer to increase the adhesion between the package structure 100a and the external circuit.

Next, in step S303, the leadframe 110 is bonded to the heat sink 130a. As described above, the leadframe 110 includes the die pad 112 and a plurality of leads 114 surrounding the die pad 112, wherein the die pad 112 is disposed in the central area 132a of the top surface 132 of the heat sink 130a through its lower surface 112b, and is electrically connected to the heat sink 130a. Each lead 114 has an inner lead portion 114a and an outer lead portion 114b, and the inner lead portion 114a of each lead 114 is disposed above the peripheral area 132b.

To increase adhesion and conductivity between the die pad 112 and the heat sink 130a, before the leadframe 110 is bonded to the heat sink 130a, a second adhesion layer 172 is formed on the heat sink 130a, so that the die pad 112 can be fixed on the heat sink 130a through the second adhesion layer 172, wherein a material of the second adhesion layer 172 is, for example, a conductive adhesive or a conductive adhesive plus a copper sheet.

Next, a first adhesion layer 170 is formed on the upper surface 112a of the die pad 112, wherein the material of the first adhesion layer 170 includes a conductive adhesive. Next, in step 5304, the chip 120 is bonded to the upper surface 112a of the die pad 112, so that the chip 120 is fixed on the die pad 112 through the first adhesion layer 170. Next, a wire bonding process is performed to form the first bonding wires 162, the second bonding wires 164 and the third bonding wires 166, wherein the first bonding wire 162 is connected between the chip 120 and the inner lead portion 114a of the corresponding lead 114, the second bonding wire 164 is connected between the chip 120 and the die pad 112, and the third bonding wire 166 is connected between the die pad 112 and the inner lead portion 114a of the corresponding lead 114. The chip 120 is electrically connected to the leads 114 and the die pad 112 of the leadframe 110 through the first bonding wires 162 and the second bonding wires 164. In the present embodiment, a material of the first bonding wire 162, the second bonding wire 164 and the third bonding wire 166 includes gold, copper, silver, aluminium or alloys thereof.

Finally, in step S305, a molding process is performed to form the molding compound 150 to encapsulate the chip 120, the die pad 112, the inner lead portion 114a of each lead 114, and the heat sink 130a, and expose the bottom surface 134 of the heat sink 130a and the outer lead portion 114b or each lead 114, wherein the bottom surface 134 of the head sink 130a and the lower surface of the molding compound 150 are coplanar. In the present embodiment, since the insulating layer 140 covers the peripheral area 132b of the top surface 132 of the heat sink 130a, namely, the peripheral area 132b of the top surface 132 of the heat sink 130a is an insulating area, during the molding process, a situation that the inner lead portion 114a of each lead 114 located above the peripheral area 132b of the top surface 132 of the heat sink 130a contacts the heat sink 130a to form a short-circuit due to a hydraulic pressure generated by plastic potting can be avoided. In other words, the package process of the present embodiment has a better manufacturing yield. Until now, manufacturing of the package structure 100a is completed.

Certainly, the manufacturing method of the package structure 100a shown in FIG. 2, and FIGS. 3A-3C is only used as an example, and a part of the steps is the commonly used technique in the current package process. Those have ordinary skill in the art can adjust, omit or increase suitable steps according to an actual demand, so as to cope with the manufacturing process, and detailed descriptions thereof is not repeated.

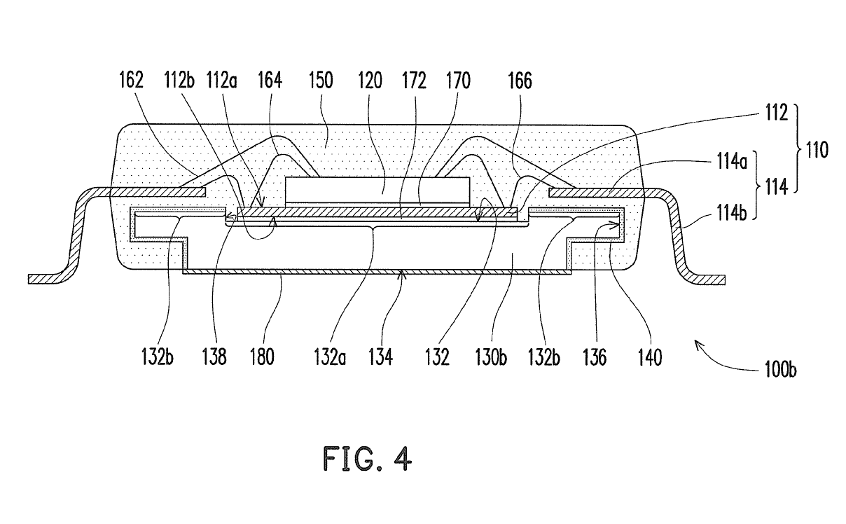

FIG. 4 is a cross-sectional view of a package structure according to another embodiment of the present invention. The present embodiment still use the reference numerals and a part of the contents of the aforementioned embodiment, wherein like reference numerals denote the same or like elements throughout, and descriptions of the same technical contents are omitted. The aforementioned embodiment can be referred for the descriptions of the omitted part of the present embodiment, so that detailed descriptions thereof are not repeated.

Referring to FIG. 4, a main difference between the package structure 100b of the present embodiment and the package structure 100a of the aforementioned embodiment is that the heat sink 130b has a containing groove 138. The containing groove 138 is located in the central area 132a of the top surface 132, and the die pad 112 is located in the containing groove 138. Since the heat sink 130b has the containing groove 138, besides a position of the die pad 112 is limited, a delamination phenomenon between the die pad 112 and the heat sink 130b can be avoided.

A manufacturing method of the package structure 100b of the present embodiment is approximately the same to that of the package structure 100a of the aforementioned embodiment, and before the step S302, i.e. before the insulating layer 140 is formed on the heat sink 130b, the containing groove 138 is formed in the central area 132a of the top surface 132. Next, the steps S303-S305 are sequentially performed to approximately complete the fabrication of the package structure 100b.

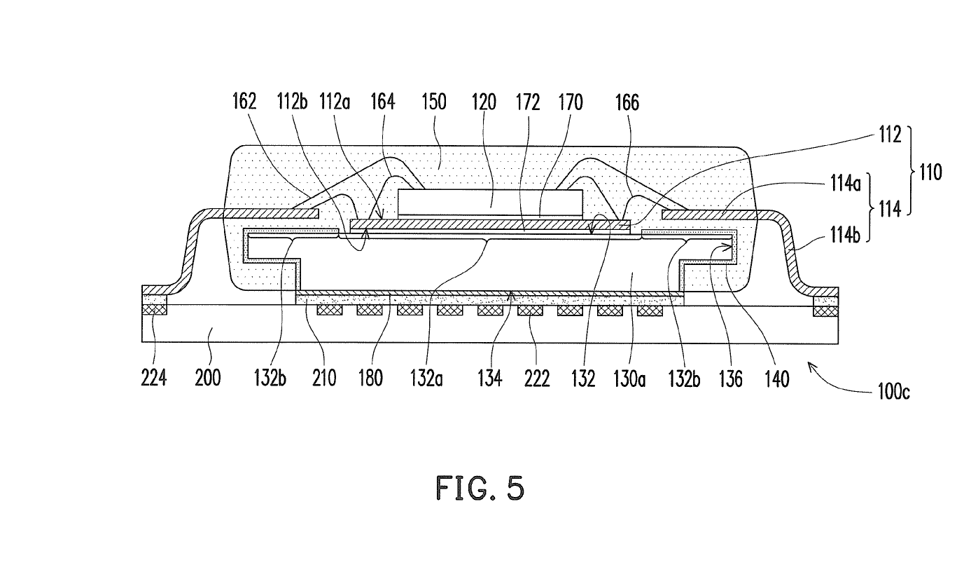

FIG. 5 is a cross-sectional view of a package structure according to another embodiment of the present invention. The present embodiment still use the reference numerals and a part of the contents of the aforementioned embodiment, wherein like reference numerals denote the same or like elements throughout, and descriptions of the same technical contents are omitted. The aforementioned embodiment can be referred for the descriptions of the omitted part of the present embodiment, so that detailed descriptions thereof are not repeated.

Referring to FIG. 5, a main difference between the package structure 100c of the present embodiment and the package structure 100a of the aforementioned embodiment is that the package structure 100c (i.e. an electronic assembly) further includes a circuit board 200, a solder layer 210 and a solder mask layer (not shown), wherein the solder layer 210 is disposed between the bottom surface 134 of the heat sink 130a and the circuit board 200, and between the outer lead portions 114b and the circuit board 200, so that the heat sink 130a and the die pad 112 are electrically connected to the circuit board 200 through the solder layer 210, and the outer lead portion 114b of each lead 114 is also electrically connected to the circuit board 200 through the solder layer 210. A material of the solder layer 210 includes tin or tin alloy.

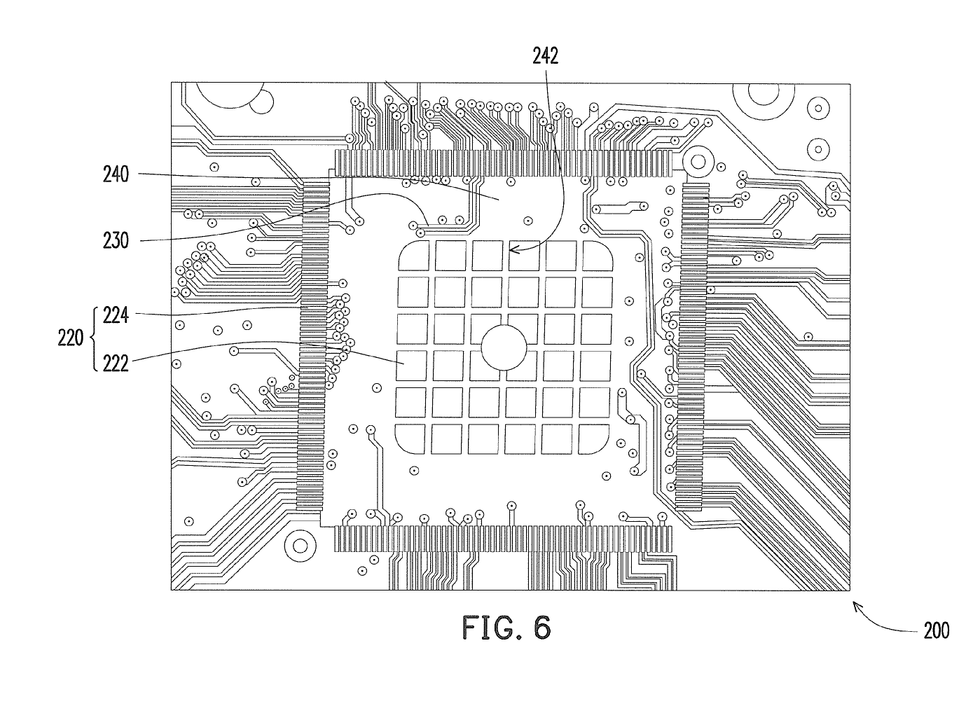

In detail, referring to FIG. 6, in the present embodiment, the circuit board 200 includes a first surface 200a and a second surface 200b opposite to the first surface 200a, wherein the first surface 200a is covered with at least a patterned conductive layer 220 and at least a wiring layer 230. The patterned conductive layer 220 has at least a first pad 222 and at least a second pad 224, wherein the first pad 222 is electrically connected to the bottom surface 134 of the heat sink 130a, and the second pad 224 is electrically connected to at least one end of the outer lead portion 114b. The solder mask layer 240 is disposed on the patterned conductive layer 220, and at least one opening 242 of the solder mask layer 240 exposes the first pad 222 and the second pad 224. Moreover, the first pad 222 is a power pad or a ground pad, and the second pad 224 is a signal pad or a ground pad.

Since the wetting layer 180 covers the bottom surface 134 of the heat sink 130a that is not covered by the insulating layer 140, when the heat sink 130a and the die pad 112 are electrically connected to the circuit board 200 through the solder layer 210, the wetting layer 180 can also function as an adhesion layer to increase the adhesion between the heat sink 130a and the solder layer 210. Moreover, the heat sink 130a and the die pad 112 are electrically connected to a power end (not shown) or a ground end (not shown) of the circuit board 200.

In addition, in other embodiments that are not illustrated, the aforementioned heat sink 130b having the containing groove 138 can also be used, and those with ordinary skill in the art can refer the descriptions of the aforementioned embodiment to select the aforementioned elements according to an actual demand, so as to achieve a required technical effect.

A manufacturing method of the package structure 100c of the present embodiment is approximately the same to that of the package structure 100a of the aforementioned embodiment, and after the step S305, i.e. after the molding compound 150 is formed, the circuit board 200 is provided, wherein the outer lead portion 114b of each lead 114 is electrically connected to the circuit board 200. Next, the solder mask layer 240 is formed on the patterned conductive layer 220, and the opening 242 of the solder mask layer 240 exposes the first pad 222 and the second pad 224. Finally, the solder layer 210 is formed between the bottom surface 134 of the heat sink 130a and the circuit board 200, so that the heat sink 130a and the die pad 112 are electrically connected to the circuit board 200 through the solder layer 210, and the manufacturing process of the package structure 100c (i.e. the electronic assembly) is approximately completed.

In summary, since the insulating layer of the package structure of the present invention covers the side surface and the peripheral area of the top surface of the heat sink, during the molding process, a situation that the inner lead portion of each lead located above the peripheral area of the top surface of the heat sink contacts the heat sink to form a short-circuit due to a hydraulic pressure generated by plastic potting can be avoided, so as to maintain a good production yield. Moreover, since the insulating layer of the package structure does not cover the bottom surface and the central area of the top surface of the heat sink, when the die pad of the leadframe is disposed in the central area of the top surface of the heat sink, and the chip is disposed on the die pad, the chip can be electrically connected to external circuit through the die pad and the heat sink under the die pad, so that the heat generated by the chip can be quickly dissipated to external through an area of the heat sink that is uncovered by the insulating layer.

Therefore, the package structure of the present invention has a better electrical performance and heat-dissipation capacity. Moreover, the heat sink can further have a containing groove, so that besides a position of the die pad can be limited, a delamination phenomenon between the die pad and the heat sink can be avoided.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A quad flat package (QFP) structure having an exposed heat sink, comprising:
a leadframe, comprising a die pad and a plurality of leads surrounding the die pad, wherein the die pad has an upper surface and a lower surface opposite to the upper surface, and each lead has an inner lead portion and an outer lead portion;
a chip, disposed on the upper surface of the die pad and electrically connected to the die pad and the leads of the leadframe;
a heat sink, having a top surface, a bottom surface opposite to the top surface, and a side surface connected between the top surface and the bottom surface, wherein the top surface has a central area and a peripheral area surrounding the central area, the die pad is disposed in the central area of the top surface of the heat sink through its lower surface, and is electrically connected to the heat sink, and the inner lead portion of each lead is disposed above the peripheral area; and
a molding compound, encapsulating the chip, the die pad, the inner lead portion of each lead and the heat sink, and exposing the bottom surface of the heat sink and the outer lead portion of each lead, wherein the bottom surface of the heat sink is capable of being electrically conducted to external.

2. The QFP structure having the exposed heat sink as claimed in claim 1, further comprising an insulating layer, wherein the insulating layer at least covers the peripheral area of the top surface or the side surface of the heat sink.

3. The QFP structure having the exposed heat sink as claimed in claim 1, wherein the heat sink has a containing groove disposed in the central area, and the die pad is disposed in the containing groove.

4. The QFP structure having the exposed heat sink as claimed in claim 1, further comprising at least a first bonding wire and at least a second bonding wire, wherein the first bonding wire is electrically connected to the inner lead portion of the corresponding lead and the chip, and the second bonding wire is electrically connected to the chip and the die pad.

5. The QFP structure having the exposed heat sink as claimed in claim 1, further comprising at least a third bonding wire, wherein the third bonding wire is electrically connected to the die pad and the inner lead portion of the corresponding lead.

6. The QFP structure having the exposed heat sink as claimed in claim 1, further comprising an adhesion layer disposed between the die pad and the heat sink wherein the adhesion layer comprises a conductive adhesive plus a copper sheet.

7. The QFP structure having the exposed heat sink as claimed in claim 1, wherein a material of the heat sink comprises copper or aluminium.

8. The QFP structure having the exposed heat sink as claimed in claim 1, further comprising a wetting layer, wherein the wetting layer is disposed on the bottom surface of the heat sink, and covers the bottom surface of the heat sink.

9. The QFP structure having the exposed heat sink as claimed in claim 8, wherein a material of the wetting layer comprises tin or tin alloy.

10. An electronic assembly, comprising:
a QFP structure, comprising:
a leadframe, comprising a die pad and a plurality of leads surrounding the die pad, wherein the die pad has an upper surface and a lower surface opposite to the upper surface, and each lead has an inner lead portion and an outer lead portion;
a chip, disposed on the upper surface of the die pad and electrically connected to the die pad and the leads of the leadframe;
a heat sink, having a top surface, a bottom surface opposite to the top surface, and a side surface connected between the top surface and the bottom surface, wherein the top surface has a central area and a peripheral area surrounding the central area, the die pad is disposed in the central area of the top surface of the heat sink through its lower surface, and is electrically connected to the heat sink, and the inner lead portion of each lead is disposed above the peripheral area;
a molding compound, encapsulating the chip, the die pad, the inner lead portion of each lead and the heat sink, and exposing the bottom surface of the heat sink and the outer lead portion of each lead, wherein the bottom surface of the heat sink is capable of being electrically conducted to external;
a circuit board, the QFP structure being disposed on the circuit board, and the circuit board having a first surface and a second surface opposite to the first surface, wherein the first surface is covered with at least a patterned conductive layer and at least a wiring layer, the patterned conductive layer has at least a first pad and at least a second pad, wherein the first pad is electrically connected to the bottom surface of the heat sink, and the second pad is electrically connected to at least one end of the outer lead portion;
at least one solder mask layer, disposed on the patterned conductive layer, and at least one opening of the solder mask layer exposing the first pad and the second pad; and
a solder layer, disposed between the bottom surface of the heat sink of the QFP structure and the circuit board, and between the outer lead portion and the circuit board, and electrically connected to the QFP structure and the circuit board.

11. The electronic assembly as claimed in claim 10, wherein the QFP structure further comprises an insulating layer, and the insulating layer at least covers the side surface or the peripheral area of the top surface of the heat sink.

12. The electronic assembly as claimed in claim 10, wherein a material of the solder layer comprises tin or tin alloy.

13. The electronic assembly as claimed in claim 10, further comprising an adhesion layer disposed between the die pad and the heat sink wherein the adhesion layer comprises a conductive adhesive plus a copper sheet.

14. The electronic assembly as claimed in claim 10, wherein a material of the heat sink comprises copper or aluminium.

15. A manufacturing method of a QFP structure having an exposed heat sink, comprising:
providing the heat sink having a top surface, a bottom surface opposite to the top surface, and a side surface connected between the top surface and the bottom surface, wherein the top surface has a central area and a peripheral area surrounding the central area;
bonding a leadframe to the heat sink, wherein the leadframe comprises a die pad and a plurality of leads surrounding the die pad, wherein the die pad has an upper surface and a lower surface opposite to the upper surface, the die pad is disposed in the central area of the top surface of the heat sink through its lower surface, and is electrically connected to the heat sink, each lead has an inner lead portion and an outer lead portion, and the inner lead portion of each lead is disposed above the peripheral area;
bonding a chip to the upper surface of the die pad, wherein the chip is electrically connected to the die pad and the leads of the leadframe; and
forming a molding compound to encapsulate the chip, the die pad, the inner lead portion of each lead and the heat sink, and expose the bottom surface of the heat sink and the outer lead portion of each lead, wherein the bottom surface of the heat sink is capable of being electrically conducted to external.

16. The manufacturing method of the QFP structure having the exposed heat sink as claimed in claim 15, further comprising forming an insulating layer on the heat sink, wherein the insulating layer at least covers the peripheral area of the top surface or the side surface of the heat sink.

17. The manufacturing method of the QFP structure having the exposed heat sink as claimed in claim 15, wherein a material of the heat sink comprises copper or aluminium.

18. The manufacturing method of the QFP structure having the exposed heat sink as claimed in claim 16, wherein the step of forming the insulating layer on the heat sink comprises:
adhering an adhesive tape to the bottom surface or the central area of the top surface of the heat sink;
forming the insulating layer on the side surface or the peripheral area of the top surface of the heat sink by electroplating; and
removing the adhesive tape to expose the bottom surface and the central area of the heat sink.

19. The manufacturing method of the QFP structure having the exposed heat sink as claimed in claim 15, further comprising forming a wetting layer on the bottom surface of the heat sink by electroplating to cover the bottom surface of the heat sink.

20. The manufacturing method of the QFP structure having the exposed heat sink as claimed in claim 19, wherein a material of the wetting layer comprises tin or tin alloy.
